(19) United States
(12) Patent Application Publication
(10) Pub. No.: US 2023/0258737 A1
(43) Pub. Date: Aug. 17, 2023

(54) POWER SUPPLY PRE-EMPTIVE FAILURE DETECTION

(71) Applicant: ARRIS Enterprises LLC, Suwanee, GA (US)

(72) Inventor: Andrew E. NEWCOMBE, Livingston (GB)

(21) Appl. No.: 18/101,786

(22) Filed: Jan. 26, 2023

Related U.S. Application Data
(60) Provisional application No. 63/309,156, filed on Feb. 11, 2022.

(51) Int. Cl. G01R 31/40; H02J 3/00; G01R 19/165; G01R 31/64

(52) U.S. Cl. CPC G01R 31/40; H02J 3/0012; G01R 19/16576; G01R 31/64; G01R 19/16585

(57) ABSTRACT

Customer premise equipment (CPE) device may include a power supply failure detector that includes an input to receive an input supply voltage from the power supply, a filter to receive the input supply voltage and produce a filtered input ripple voltage having a predetermined frequency range, a peak detector to process the filtered input ripple voltage from the filter to generate a peak value signal having an amplitude indicative of the peak value of the filtered input ripple voltage, and a level detector to process the peak value signal to generate a signal indicative of a fault condition of the power supply based on the filtered input ripple voltage being determined to be greater than the predetermined peak input ripple voltage. AC coupling may be provided at the input remove DC components from the input supply voltage. An amplifier may amplify the input supply voltage.

### BACKGROUND

The subject matter of the present disclosure relates generally to an electronic device having a detector for determining when power input from a power supply to the electronic device exhibits a degraded performance characteristic.

Electronic devices, such as Customer Premise Equipment (CPE), are often powered by an external power supply. CPE devices may be Non-limiting examples of CPE may include set-top boxes (STBs), smart media devices (SMDs), routers, network switches, residential gateways (RG), high-speed cable modems, extenders, fixed mobile convergence products, home networking adapters and Internet access gateways, digital subscriber line (DSL) or other broadband Internet routers, VoIP base stations, etc. These devices along with the power are provided to a user by a services provider, such as a cable provider, satellite provider, etc. The external power supply connects one end to an electrical receptacle to receive alternating current (AC) voltage and converts the AC voltage to a predetermined direct current (DC) input voltage. The external power supply connects at a second end to the electronic device to provide the predetermined DC input voltage to the electronic device.

An external power supply may be rated for an output of 30 W with output voltage ripple of ±120 millivolts (mV). For example, a power supply may be designed to provide a +12 volt output with an output voltage ripple of ±120 mV. The reliability target of the power supply units is for an annualized Failure Rate of <0.3%/year. Power supplies are generally designed for an expected design life of 5 years at an ambient temperature of 50° C. A bathtub curve describes failures versus time, where there is a decreasing rate for early failures, a period of a relatively constant failure rate due to random failures during the useful life of the power supply, and finally an increasing rate of deterioration failures as the power supply exceeds its designed lifetime.

The power supply can see a significant internal temperature rise during operation. This elevated temperature causes stress on internal components. As the power supply get towards the end of the 5 year design life and goes beyond it, these components, such as capacitors, may fail. When the components degrade, typically the output voltage starts to deviate further from the specified output voltage. As the components in the power supply age, typically the level of voltage ripple observed on the regulated +12V power supply will increase. This will eventually exceed the specified value input ripple voltage of ±120 mV. However, in practice, the CPE is robust to excessive ripple and will continue to operate. When the power supply begins to degrade, the output voltage ripple may exceed ±120 mV and cause the electronic device to become unusable by the customer.

A power supply failure will result in the CPE being unusable by the customer until a new unit can be delivered and installed. However, in the event of a power supply failure, it may be unclear to the end user whether the fault lies in the power supply or the CPE itself. This frequently requires both a power supply and set top box to be provided.

### SUMMARY

An aspect of the present disclosure involves an electronic device having a detector for determining when power input from a power supply to the electronic device exhibits a degraded performance characteristic.

Customer premise equipment (CPE) device may include a power supply failure detector that includes an input, coupled to a power supply, to receive an input supply voltage from the power supply, a filter, coupled to the input, the filter receiving the input supply voltage to produce a filtered input ripple voltage having a predetermined frequency range, a peak detector, coupled to the filter, to process the filtered input ripple voltage from the filter to generate a peak value signal having an amplitude indicative of the peak value of the filtered input ripple voltage, and a level detector, coupled to the peak detector, to process the peak value signal to generate a signal indicative of a fault condition of the power supply based on the filtered input ripple voltage being determined to be greater than the predetermined peak input ripple voltage.

The CPE may include a processor, coupled to the level detector, to provide the signal indicative of the fault condition of the power supply to a broadband service provider.

The CPE may include a processor, coupled to the level detector, wherein the processor logs the fault condition, and provides the signal indicative of the fault condition to a broadband service provider when the fault condition is logged more than a predetermined number of times over a predetermined period.

The fault condition may be provided to a broadband service provider as an indication to replace the power supply.

The CPE may further include an alternating current (AC) coupling at the input to receive the input supply voltage and to produce the input supply voltage having direct current (DC) voltage removed from the input supply voltage, and an amplifier, coupled to the AC coupling, to amplify the input supply voltage having the DC voltage removed from the input supply voltage, wherein the filter comprises a bandpass filter that passes frequencies within the predetermined frequency range and rejects frequencies outside the predetermined frequency range.

The input supply voltage is a positive 12 volts having an input ripple voltage of ±120 millivolts.

The signal indicative of the fault condition of the power supply may be an indication of a capacitor failure in the power supply.

### BRIEF SUMMARY OF THE DRAWINGS

The accompanying drawings, which are incorporated in and form a part of the specification, illustrate examples of the subject matter of the present disclosure and, together with the description, serve to explain the principles of the present disclosure. In the drawings:

FIG. 1 is a system diagram.

FIG. 2 illustrates a block diagram of a Customer Premise Equipment (CPE) device.

FIG. 3 illustrates a block diagram of a Power Supply Pre-Emptive Failure Detector (PS Failure Detector).

FIG. 4 is one example of a circuit diagram of a Power Supply Pre-Emptive Failure Detector (PS Failure Detector).

FIG. 5 is a flow chart of a method for providing pre-emptive failure detection of a power supply for Customer Premise Equipment (CPE).

FIG. 6 illustrates a block diagram of a network device.

### DETAILED DESCRIPTION

The following detailed description is made with reference to the accompanying drawings and is provided to assist in a comprehensive understanding of various example embodiments of the present disclosure. The following description includes various details to assist in that understanding, but these are to be regarded merely as examples and not for the purpose of limiting the present disclosure as defined by the appended claims and their equivalents. The words and phrases used in the following description are merely used to enable a clear and consistent understanding of the present disclosure. In addition, descriptions of well-known structures, functions, and configurations may have been omitted for clarity and conciseness.

Aspects of the present disclosure are directed to an electronic device having a detector for determining when power input from a power supply to the electronic device exhibits a degraded performance characteristic. Customer premise equipment (CPE) device may include a power supply failure detector that includes an input, coupled to a power supply, to receive an input supply voltage from the power supply, a filter, coupled to the input, the filter receiving the input supply voltage to produce a filtered input ripple voltage having a predetermined frequency range, a peak detector, coupled to the filter, to process the filtered input ripple voltage from the filter to generate a peak value signal having an amplitude indicative of the peak value of the filtered input ripple voltage, and a level detector, coupled to the peak detector, to process the peak value signal to generate a signal indicative of a fault condition of the power supply based on the filtered input ripple voltage being determined to be greater than the predetermined peak input ripple voltage. The CPE may include a processor, coupled to the level detector, to provide the signal indicative of the fault condition of the power supply to a broadband service provider. The CPE may include a processor, coupled to the level detector, wherein the processor logs the fault condition, and provides the signal indicative of the fault condition to a broadband service provider when the fault condition is logged more than a predetermined number of times over a predetermined period. The fault condition may be provided to a broadband service provider as an indication to replace the power supply. The CPE may further include an alternating current (AC) coupling at the input to receive the input supply voltage and to produce the input supply voltage having direct current (DC) voltage removed from the input supply voltage, and an amplifier, coupled to the AC coupling, to amplify the input supply voltage having the DC voltage removed from the input supply voltage, wherein the filter comprises a bandpass filter that passes frequencies within the predetermined frequency range and rejects frequencies outside the predetermined frequency range. The input supply voltage is a positive 12 volts having an input ripple voltage of ±120 mv. The signal indicative of the fault condition of the power supply may be an indication of a capacitor failure in the power supply.

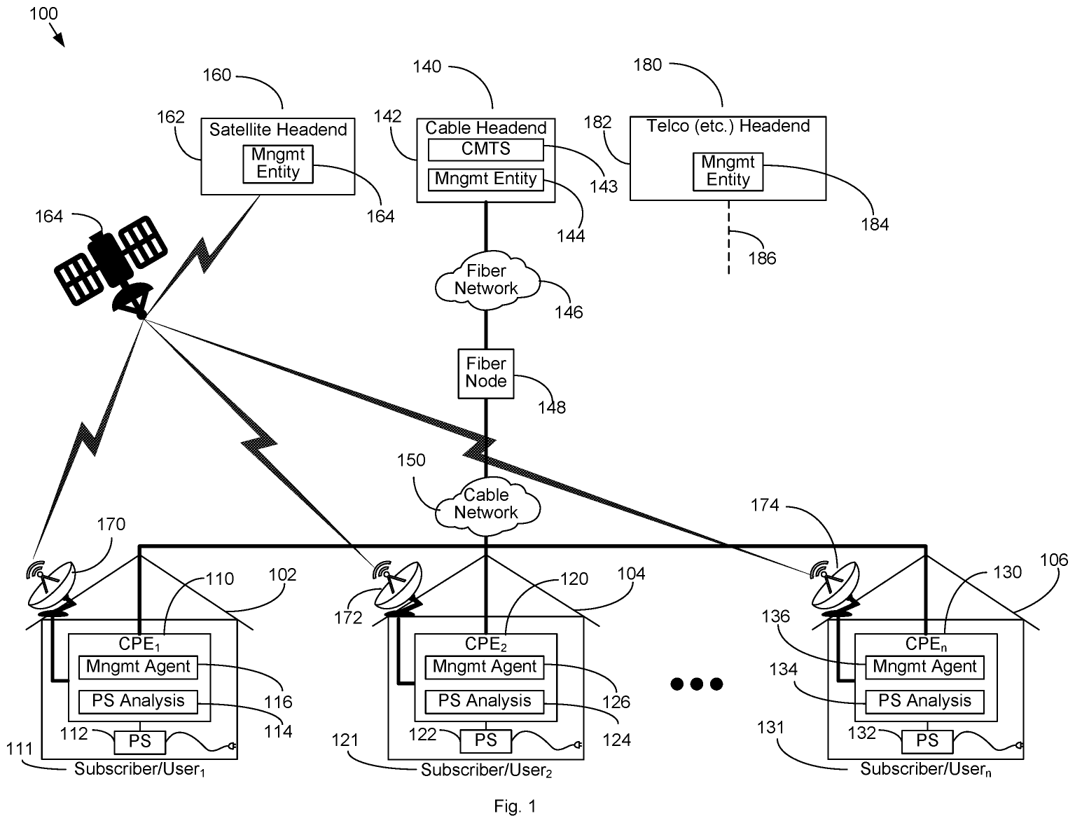

FIG. 1 is a system diagram 100.

FIG. 1 shows three residences 102, 104, 106. The three residences 102, 104, 106 are associated with Subscriber/User₁ 111, Subscriber/User₂ 121, Subscriber/Userₙ 131, respectively. Residence 102 has Customer Premise Equipment 1 (CPE₁) 110. CPE 110 includes a management agent 116 and a Power Supply (PS) Analysis component 114. A Power Supply 112 provides direct current (DC) input voltage to CPE 110, wherein PS Analysis component 114 analyzes the DC input voltage to determine when the DC input voltage from Power Supply (PS) 112 exhibits a degraded performance characteristic.

Residence 104 has CPE₂ 120. CPE₂ 120 includes a management agent 126 and a PS Analysis component 124. PS 122 provides DC input voltage to CPE₂ 120, wherein PS Analysis component 124 analyzes the DC input voltage to determine when the DC input voltage from PS 122 exhibits a degraded performance characteristic. Residence 106 has CPE₃ 130 includes a management agent 136 and a PS Analysis component 134. APS 132 provides DC input voltage to CPE₃ 130, wherein PS Analysis component 134 analyzes the DC input voltage to determine when the DC input voltage from PS 132 exhibits a degraded performance characteristic. PS 112, 122, 132 may be designed to provide +12 volt DC output with an output voltage ripple of ±120 millivolts (mV). As the components in the power supply age, typically the level of voltage ripple observed on the regulated +12V power supply will increase. This will eventually exceed the specified value input ripple voltage of ±120 mV. The increase in the voltage ripple may cause the CPE to become unusable by the subscriber/user.

CPE₁ 110, CPE₂ 120, CPE₃ 130 includes any equipment in the “customers' premises” (or other appropriate locations) that is used for accessing the Internet or generally accessing services or content on a provider network. CPE₁ 110, CPE₂ 120, CPE₃ 130 includes equipment that is provided by a broadband service provider, such as a Cable Operator 140, satellite provider 160, telecommunications company 180, etc. Broadband service providers may provide Internet service, deliver content, provide Voice-over Internet Protocol (VoIP) service, etc. CPE₁ 110, CPE₂ 120, CPE₃ 130 typically communicates with the broadband service provider's infrastructure (which may be referred to generally as the “headend”), which then connects to a wider network such as the Internet 160 or a private network (not shown). CPE₁ 110, CPE₂ 120, CPE₃ 130 are located on the customer side of the network and can be a demarcation point between the provider network (Wide Area Network (WAN)) and the customer's home network or (Local Area Network (LAN)). Non-limiting examples of CPE₁ 110, CPE₂ 120, CPE₃ 130 include set-top boxes (STBs), smart media devices (SMDs), routers, network switches, residential gateways (RG), high-speed cable modems, extenders, fixed mobile convergence products, home networking adapters and Internet access gateways, digital subscriber line (DSL) or other broadband Internet routers, VoIP base stations, etc. CPE₁ 110, CPE₂ 120, CPE₃ 130 may be directly or indirectly connected to Cable Headend 142. Cable Headend 142 is connected to Fiber Network 144. Cable Headend 142 may include a Cable Modem Termination System (CMTS) 143 that exchanges digital signals with CPE₁ 110, CPE₂ 120, CPE₃ 130. Cable Headend 142 receives (upstream) and transmits (downstream) analog radio-frequency (RF) signals over coaxial cable to communicate with CPE₁ 110, CPE₂ 120, CPE₃ 130. Cable Headend 142 is connected to Fiber Network 146. Fiber Network 146 may use coaxial cable to distribute RF signals. Upon leaving Cable Headend 142, analog RF signals are generally converted to analog optical signals which are carried over fiber-optic cables. The point at which a fiber run terminates is called a Fiber Node 148. At Fiber Node 148, the analog optical signals are converted back to RF electrical signals and delivered over coaxial cable by Cable Network 150 to CPE₁ 110, CPE₂ 120, CPE₃ 130. FIG. 1 also shows a Satellite Headend 162 that provides signals to Satellite 164, which are then received at Residences 102, 104, 106 by Satellite Receivers 170, 172, 174, respectively. As explained above, a Telecommunications Company (Telco) 180 may also provide broadband services to CPE₁ 110, CPE₂ 120, CPE₃ 130 via Telecommunications Network 186.

Network management protocols may be used by Management Agents 116, 126, 136 of CPE₁ 110, CPE₂ 120, CPE₃ 130, respectively, and Management Entities 144, 164, 184 of Headends 142, 162, 182 of broadband service providers 140, 160, 180, respectively, to monitor network and system configuration information, to measure network performance conditions so that performance can be maintained at an acceptable level, and to detect events, log events, send notifications, and address problems to maintain effective performance of the network and network devices, including CPE₁ 110, CPE₂ 120, CPE₃ 130. Management Agent 116 of CPE₁ 110, Management Agent 126 of CPE₂ 120, and Management Agent 136 of CPE₃ 130 use such network management protocols to communicate with Management Entity 144 of Cable Headend 142, Management Entity 164 of Satellite Headend 162, and Telco Headend 182, respectively.

One Network management protocols may use Management Information Bases (MIBs) with Simple Network Management Protocol (SNMP) to remotely configure, monitor, and diagnose a device. SNMP is an Internet Standard protocol for collecting and organizing information about managed devices on IP networks and for modifying that information to change device behavior. For example, Headends 142, 162, 182 may use SNMP MIBs to send a request to CPE₁ 110, CPE₂ 120, CPE₃ 130 for diagnostics to be sent back to Headends 142, 162, 182 by CPE₁ 110, CPE₂ 120, CPE₃ 130. Management Information Base (MIB) are used to describe a set of network objects that can be managed using SNMP. SNMP allows monitoring of the health of hardware and software. SNMP-enabled devices can be monitored remotely with network monitoring tools to keep track of performance and availability. SNMP enables performance information to be relayed back to the end-user. SNMP agents, SNMP managers, Management Information Base (MIBs), and Object Identifiers (OIDs) all work together to make these transfers possible. OIDs uniquely identify managed objects in a MIB hierarchy.

SNMP agents are programs that run on CPE₁ 110, CPE₂ 120, CPE₃ 130 that are connected to the network. A SNMP agent takes information from the MIB and hands it over to the SNMP manager once a query has been made. This information includes status details about the connected device. The SNMP manager communicates with the SNMP agent devices. The SNMP manager queries agents, receives responses from agents and sets agent variables. A MIB contains all of the performance data that is accessed when loading up a network monitoring tool. The SNMP Manager and SNMP Agent relationship makes sure that the user can monitor multiple devices from one location.

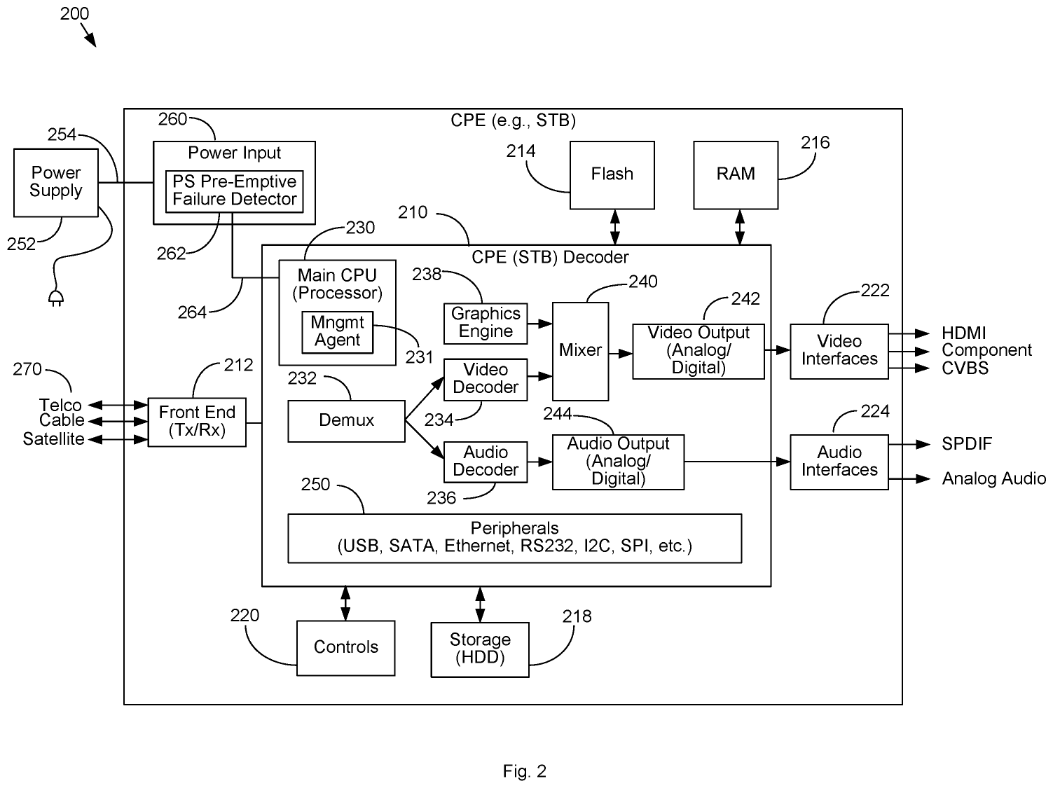

FIG. 2 illustrates a block diagram of a Customer Premise Equipment (CPE) device 200.

In FIG. 2, CPE 200 shows a configuration for a Set-Top Box (STB). However, as described above, CPE 200 may comprise other devices such as smart media devices (SMDs), routers, network switches, residential gateways (RG), high-speed cable modems, extenders, fixed mobile convergence products, home networking adapters and Internet access gateways, digital subscriber line (DSL) or other broadband Internet routers, VoIP base stations, etc. CPE 200 includes a Decoder 210. Decoder 210 provides most of the processing of the CPE 200. Decoder 210 includes the main CPU or processor 230, which implements and controls may of the operations of the CPE 200. Decoder 210 provides a Demultiplexer (Demux) 232. Demux 232 de-multiplexes a digital transport stream received via Frontend 212 from a Cable Headend, a Satellite Headend, a Telco Headend, etc. into audio, video, and other data. Demux 232 checks the input stream for errors and protocol compliance and filters the required data into desired buffers (e.g., audio, video).

Video Decoder 234 converts compressed video data, e.g., Moving Picture Experts Group (MPEG) file format, into a basic video format, such as MPEG2, H.264, VC1, etc. MPEG format files hold compressed data by storing only changes that occur between each frame instead of keeping every frame of the video. H.264 is a member of the H.26x line of VCEG video coding standards from the of the International Telecommunication Union (ITU)-Telecommunication Standardization Sector (ITU-T). VC-1 is an evolution of the conventional block-based motion-compensated hybrid video coding design also found in H.261, MPEG-1 Part 2, H.262/MPEG-2 Part 2, H.263, and MPEG-4 Part 2.

Graphics Engine 238 is dedicated to graphics acceleration for presenting pictures and menus, for example, for a user interface (UI). Mixer 240 mixes the video output from Video Decoder 234 and graphics output from Graphics Engine 238 to producing a final single image. Mixer 240 also orders the video and graphics plane and transparency settings. Video Output 242 provides the final result of Mixer 240 according to an appropriate standard, e.g., Phase Alternating Line (PAL), National Television Standards Committee (NTSC), Sequential Color and Memory (SECAM), High-Definition Multimedia Interface (HDMI), etc. Video Output 242 generates output in analog format using DACs and generates output in digital format using HDMI convertors.

Audio Decoder 236 converts compressed audio data into basic audio data, such as MPEG, Advanced Audio Coding (AAC), Dolby formats. Audio Output 244 provides audio output in an analog format using internal digital-to-analog converters (DACs) and in digital format using a Sony/Philips Digital Interface (S/PDIF) convertor. Processor 230 provides decoding to support various Peripherals 250: Universal Serial Bus (USB) for record/playback on external storage, Serial Advanced Technology Attachment (SATA) to connect a hard disk drive (HDD) for providing digital video recording facility, Ethernet for Internet Protocol (IP) based data, Universal Asynchronous Receiver-Transmitter (UART) for providing a debug port and for uploading local software upgrades, Inter-Integrated Circuit (I2C) bus to communicate with external peripheral devices, such as front end controllers, HDMI controller etc., and Serial Peripheral Interface (SPI) for connecting to non-volatile storage on serial flash devices.

CPE 200 includes a Frontend 212 for communicating signals between CPE 200 and broadband network services 270, demodulating signals and outputting digital data output for the Decoder 210. Frontend 212 unit may include tuners to tune to a correct frequency, a demodulator, and forward error correction (FEC) unit for data recovery. Flash 214 is used to store non-volatile information, such as a boot loader program, a main application and other user specific non-volatile data. Random Access Memory (RAM) 216 is used to store all intermediate data (such as decoded video/audio buffers) and application variables. The main application may also be copied to RAM 216 for execution to speed up the operation.

Video Interfaces 222 receives output video data from Decoder 210 in analog or digital format and makes these signals compatible with external devices, e.g., in HDMI, Component, Composite Video Baseband Signal (CVBS), or other formats. Audio Interfaces 224 received audio data in analog as well as digital format from Decoder 210. Audio Interfaces 224 may include DACs to convert digital data into analog format. Digital data is also transmitted in digital format using S/PDIF standard. Storage 218 may store programs or other content, e.g., when CPE 200 includes a digital video recorder (DVR) function. Controls 220 provide an interface for user manual input and reception of signals, such as IR input/output. Controls 220 may also include status light emitting diodes (LEDs).

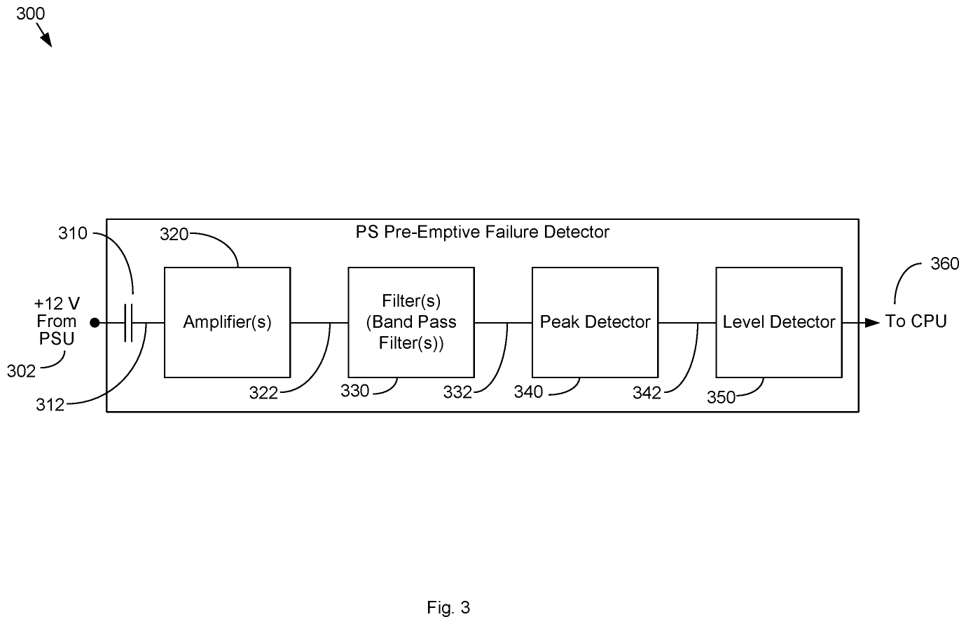

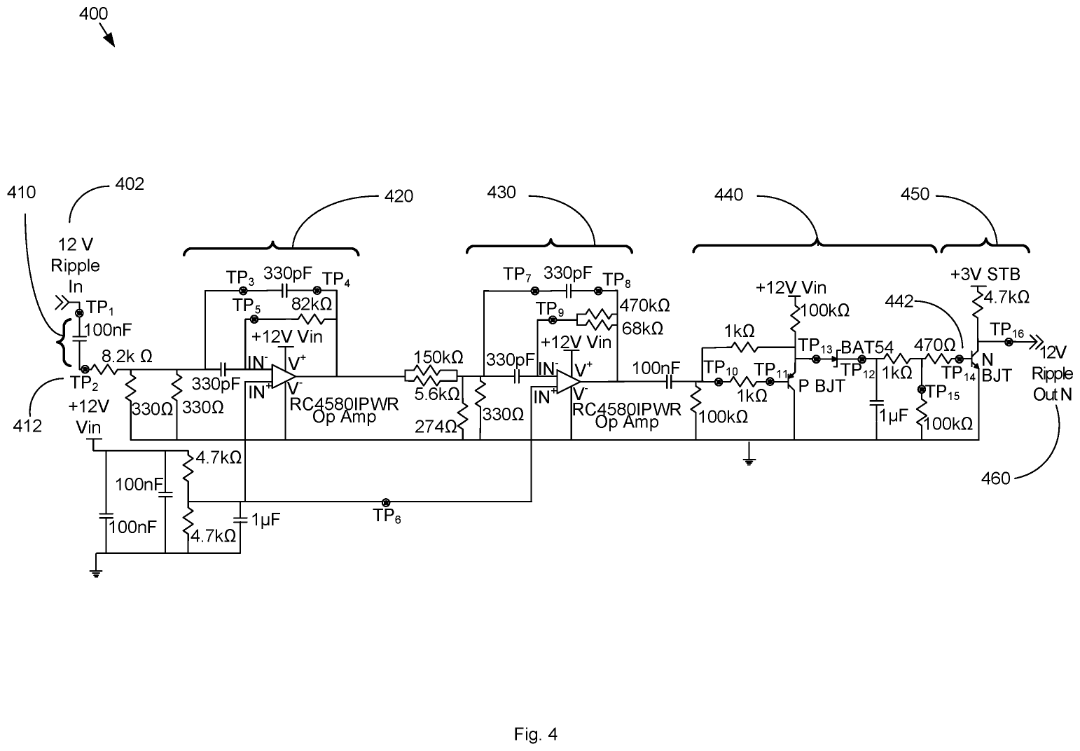

Power Supply (PS) 252 provides a predetermined input voltage 254 to Power Input 260. Power Input 260 includes a Power Supply Pre-Emptive Failure Detector (PS Failure Detector) 262. PS Failure Detector 262 includes at least an input, a filter, peak detector, and a level detector, as explained in more detail with reference to FIGS. 3-4. The input is coupled to PS 252 to receive the predetermined input supply voltage 254 from PS 252. The predetermined input supply voltage 254 from PS 252 may be a positive 12 volts having an input ripple voltage of ±120 mv.

The filter receives the input supply voltage to produce a filtered input ripple voltage having a predetermined frequency range. The output ripple for a given power supply design will have a characteristic frequency. The input ripple voltage at those frequencies are the ones that will start to increase when the capacitors start to degrade. This makes the ripple voltage from degraded components of the power supply distinguishable from other sources of voltage disturbances caused by, for example, interruptions to the power supply, failures within the set top box, other external interference, etc.

The peak detector processes the filtered input ripple voltage from the filter to generate a peak value signal having an amplitude indicative of the peak value of the filtered input ripple voltage. The peak level detect determines whether the peak value signal indicates that the filtered input ripple voltage is greater than a predetermined peak input ripple voltage and generate a signal indicative of a fault condition 264 of PS 252 based on the peak value signal has an amplitude that indicates that the filtered input ripple voltage is greater than a predetermined peak input ripple voltage. For example, the fault condition may further be an indication of a capacitor failure in the PS 252.

PS Failure Detector 262 is coupled to Processor 230 to provide the Processor 230 the signal indicative of the fault condition 264. PS Failure Detector 262 detects the characteristics of the +12V input voltage of PS 252 that has degraded performance and may imminently fail. When such an indication is detected, software can signal the condition back to the CPE provider who can then send a replacement PS 252 to the customer prior to the unit failing.

Processor 230 may log fault conditions based on the received signal indicative of the fault condition 264, and sends a management signal indicative of the fault condition to a broadband service provider via Frontend 212. Processor 230 may use Management Agent 231 to send the management signal when the fault condition is logged more than a predetermined number of times over a predetermined period. Processor may also send the management signal to the broadband service provider 270 regardless of the log count (e.g., signaling a transitory deviation of the filtered input ripple voltage from a specified ripple voltage). The fault condition may be used as an indication to broadband service provider 270 to replace PS 252. PS Failure Detector 262 may also include AC coupling and one or more amplifiers. AC coupling may be located at the input of PS Failure Detector 262 to receive the input supply voltage and to produce the input supply voltage having DC components removed from the input supply voltage so that only the AC components of the input supply voltage remains, e.g., the input ripple voltage. The one or more amplifiers may be used to amplify the input supply voltage having the DC voltage removed. The one or more filters may comprise one or more bandpass filters that pass the ripple voltage that exhibit one or more frequencies within the predetermined frequency range and reject the ripple voltage that exhibit one or more frequencies outside the predetermined frequency range.

FIG. 3 illustrates a block diagram of a Power Supply Pre-Emptive Failure Detector (PS Failure Detector) 300.

In FIG. 3, PS Failure Detector 300 includes AC coupling 310 that receives the +12 volts 302 from a power supply and removes the DC component from the input supply voltage so that only AC components of the input supply voltage remain, e.g., the input ripple voltage 312.

One or more amplifiers 320 amplify the input ripple voltage 312 to produce an amplified input ripple voltage 322. One or more filters 330 receive the amplified input ripple voltage 322 to produce a filtered input ripple voltage 332 having a predetermined frequency range. The filtered input ripple voltage has a predetermined frequency or range of frequencies. The input ripple voltage at those frequencies are the ones that will start to increase when the capacitors start to degrade.

The one or more filters 330 may comprise one or more bandpass filters that pass the ripple voltage that exhibit one or more frequencies within the predetermined frequency range and reject the ripple voltage that exhibit one or more frequencies outside the predetermined frequency range. For example, the filtered input ripple voltage for a given power supply design will have a characteristic frequency. Therefore, the one or more filters 330 are configured to remove unwanted frequency components from the input ripple voltage by completely or partially suppressing frequency components of the input ripple voltage that do not have the characteristic frequency. This makes the ripple voltage from degraded components of the power supply distinguishable from other sources of voltage disturbances caused by, for example, interruptions to the power supply, failures within the set top box, other external interference, etc.

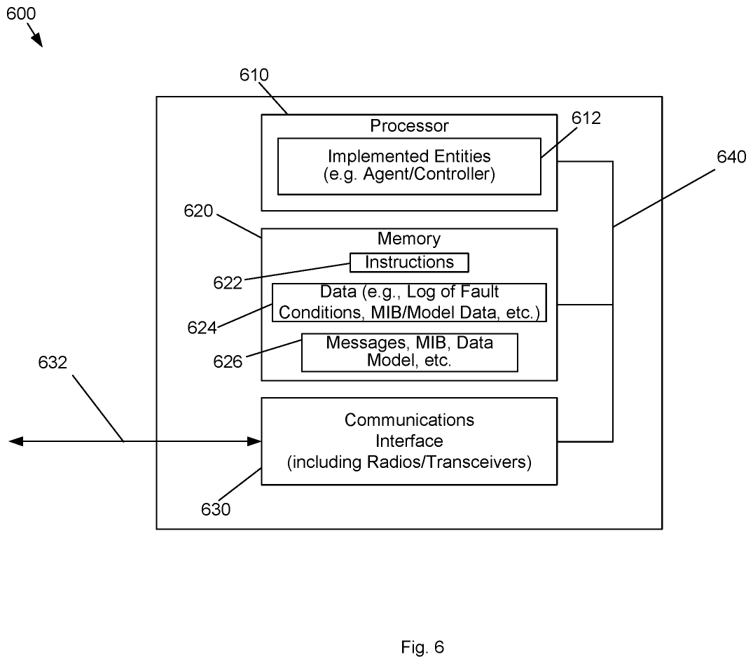

A Peak Detector 340 processes the filtered input ripple voltage 332 from the one or more filters 330 to generate a peak value signal 342 having an amplitude indicative of the peak value of the filtered input ripple voltage 332. Level Detector 350 is coupled to the Peak Detector 340 to receive the peak value signal 342 and to generate a signal indicative of a fault condition 360 of the power supply based on the filtered input ripple voltage 332 being determined to be greater than the predetermined peak input ripple voltage. Peak Detector 340 detects the characteristics of the +12V input voltage 302 of the power supply that has degraded performance and may imminently fail. When such an indication is detected, a signal indicative of a fault condition 360 of the power supply may be sent to the processor that in turns may send a management signal back to the CPE provider who can then send a replacement power supply to the customer prior to failure of the power supply. Those skilled in the art will understand that FIG. 3 illustrates only one example of a PS Failure Detector 300 and that other configurations or designs may be possible, including software implementations provided by, for example, Processor 230 shown in FIG. 3 or Processor 610 shown in FIG. 6.

FIG. 4 is one example of a circuit diagram of a Power Supply Pre-Emptive Failure Detector (PS Failure Detector) 400.

In FIG. 4, PS Failure Detector 400 includes AC coupling 410 that receives the +12 volts 402 from a power supply and removes the DC component from the input supply voltage so that only AC components of the input supply voltage remain, e.g., the input ripple voltage at Test Point 2 (TP₂) 412.

One or more amplifiers/filters 420, 430 amplify and filter the input ripple voltage to produce an amplified, filtered input ripple voltage. In FIG. 4, amplifiers/filters 420, 430 are shown as separate portions of PS Failure Detector 400, amplifiers/filters 420, 430 may be combined. Further, separate amplifiers and separate filters could be used. The filtered input ripple voltage has a predetermined frequency or range of frequencies. The filter components of amplifiers/filters 420, 430 may comprise one or more bandpass filters that pass the ripple voltage that exhibit one or more frequencies within the predetermined frequency range and reject the ripple voltage that exhibit one or more frequencies outside the predetermined frequency range. For example, the filtered input ripple voltage for a given power supply design will have a characteristic frequency. Therefore, the filter components of amplifiers/filters 420, 430 are configured to remove unwanted frequency components from the input ripple voltage by completely or partially suppressing frequency components of the input ripple voltage that do not have the characteristic frequency. This makes the ripple voltage from degraded components of the power supply distinguishable from other sources of voltage disturbances caused by, for example, interruptions to the power supply, failures within the set top box, other external interference, etc.

A peak detector 440 processes the amplified, filtered input ripple voltage from the one or more amplifier/filters 420, 430 to generate a peak value signal, e.g., at TP₁₄ 442, having an amplitude indicative of the peak value of the amplified, filtered input ripple voltage. A level detector 450 is coupled to the peak detector 440 to receive the peak value signal, e.g., at TP₁₄ 442, and to generate a signal indicative of a fault condition 460 of the power supply based on the amplified, filtered input ripple voltage being determined to be greater than the predetermined peak input ripple voltage. Those skilled in the art will understand that FIG. 4 illustrates only one example of a circuit diagram for implementing a PS Failure Detector 400 and that other configurations or designs may be possible, including software implementations provided by, for example, Processor 230 shown in FIG. 3 or Processor 610 shown in FIG. 6.

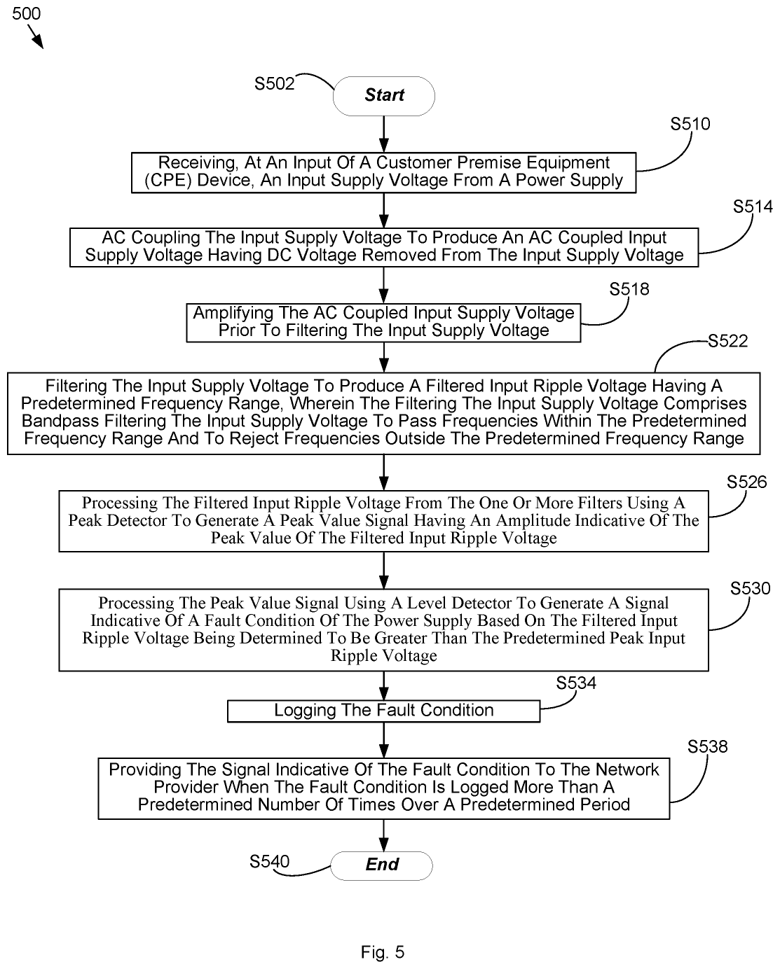

FIG. 5 is a flow chart of a method 500 for providing pre-emptive failure detection of a power supply for Customer Premise Equipment (CPE).

In FIG. 5, method 500 starts (S502), and an input supply voltage is received from a power supply at an input of a Customer Premise Equipment (CPE) device (S510). Non-limiting examples of CPE include set-top boxes (STBs), smart media devices (SMDs), routers, network switches, residential gateways (RG), high-speed cable modems, extenders, fixed mobile convergence products, home networking adapters and Internet access gateways, digital subscriber line (DSL) or other broadband Internet routers, VoIP base stations, etc. As described in FIG. 3, PS Failure Detector 300 receives the +12 volts 302 from a power supply.

The input supply voltage is AC coupled to produce an AC coupled input supply voltage having DC voltage removed from the input supply voltage (S514). As described in FIG. 3, PS Failure Detector 300 includes AC coupling 310 that receives the +12 volts 302 from a power supply and removes the DC component from the input supply voltage so that only AC components of the input supply voltage remain, e.g., the input ripple voltage 312.

The AC coupled input supply voltage is amplified prior to filtering (S518). As described in FIG. 3, one or more amplifiers 320 amplify the input ripple voltage 312 to produce an amplified input ripple voltage 322.

The input supply voltage is filtered to produce a filtered input ripple voltage having a predetermined frequency range, wherein the filtering the input supply voltage may include bandpass filtering the input supply voltage to pass frequencies within the predetermined frequency range and to reject frequencies outside the predetermined frequency range (S522). As described in FIG. 3, one or more filters 330 receive the amplified input ripple voltage 322 to produce a filtered input ripple voltage 332 having a predetermined frequency range. The one or more filters 330 may comprise one or more bandpass filters that pass frequencies within the predetermined frequency range and reject frequencies outside the predetermined frequency range. For example, the filtered input ripple voltage 332 for a given power supply design will have a characteristic frequency. This makes the ripple voltage from degraded components of the power supply distinguishable from other sources of voltage disturbances caused by, for example, interruptions to the power supply, failures within the set top box, other external interference, etc.

The filtered input ripple voltage from the one or more filters is processed using a peak detector to generate a peak value signal having an amplitude indicative of the peak value of the filtered input ripple voltage (S526). As described in FIG. 3, a peak detector 340 processes the filtered input ripple voltage 332 from the one or more filters 330 to generate a peak value signal 342 having an amplitude indicative of the peak value of the filtered input ripple voltage 332.

The peak value signal is processed using a level detector to generate a signal indicative of a fault condition of the power supply based on the filtered input ripple voltage being determined to be greater than the predetermined peak input ripple voltage (S530). As described in FIG. 3, Level Detector 350 is coupled to the Peak Detector 340 to receive the peak value signal 342 and to generate a signal indicative of a fault condition 360 of the power supply based on the filtered input ripple voltage 332 being determined to be greater than the predetermined peak input ripple voltage.

The fault condition is logged (S534). As described in FIG. 2, PS Failure Detector 262 is coupled to Processor 230 to provide the Processor 230 the signal indicative of the fault condition 264. Processor 230 may log fault conditions based on the received signal indicative of the fault condition 264, and sends a management signal indicative of the fault condition to a broadband service provider via Frontend 212.

The signal indicative of the fault condition is provided to the network provider when the fault condition is logged more than a predetermined number of times over a predetermined period (S538). However as described above, the management signal may be sent to the broadband service provider regardless of the log count (e.g., signaling a transitory deviation of the filtered input ripple voltage from a specified ripple voltage). As described in FIG. 2, Processor 230 may send the management signal when the fault condition is logged more than a predetermined number of times over a predetermined period. Processor may also send the management signal to the broadband service provider 270 regardless of the log count (e.g., signaling a transitory deviation of the filtered input ripple voltage from a specified ripple voltage).

The method then ends (S540).

FIG. 6 illustrates a block diagram of a network device 600.

In FIG. 6, Network Device 600 may be a CPE, a CMTS, or other device for detecting failure of a power supply and/or for processing management signals indicating failure of a power supply.

The Network Device 600 includes a Processor 610, Memory 620, and Communication Interface 630, including Radios/Transceivers. Processor 610, Memory 620, and Communications Interface 630 communicate via link 640. Communications Interface 630 receives and transmits data via connection 632. Connection 632 may be a wireless or wired connection and may be a fronthaul connection or a backhaul connection.

Processor 610 executes Instructions 622 in Memory 620 to implement operation of Network Device 600 including control of operation of Communication Interface 630 to provide fronthaul connections and backhaul connections via Connection 632. Processor 610 also executes Instructions 622 in Memory 620 to implement entities 612, such as Management Agents, Management Controllers, etc. Memory 620 may store data 624, such as log data associated with fault conditions, management information base (MIB)/model data, etc. for managing CPE including pre-emptive failure detection of power supplies. Memory 620 may further store messages, MIB, Data Models, etc. 626. Thus, Network Device 600 may process signals indicative of a fault condition associated with a power supply. Those skilled in the art will understand that FIG. 6 illustrates only one example of a Network Device 600, and that other configurations or designs may be possible, including configurations or designs for headend components, such as Cable Modem Termination Systems (CMTS), and CPE devices, such as set-top boxes (STBs), smart media devices (SMDs), routers, network switches, residential gateways (RGs), high-speed cable modems, extenders, fixed mobile convergence products, home networking adapters and Internet access gateways, digital subscriber line (DSL) or other broadband Internet routers, VoIP base stations, etc.

The subject matter of the present disclosure may be provided as a computer program product including one or more non-transitory computer-readable storage media having stored thereon instructions (in compressed or uncompressed form) that may be used to program a computer (or other electronic device) to perform processes or methods described herein. The computer-readable storage media may include one or more of an electronic storage medium, a magnetic storage medium, an optical storage medium, a quantum storage medium, or the like. For example, the computer-readable storage media may include, but are not limited to, hard drives, floppy diskettes, optical disks, read-only memories (ROMs), random access memories (RAMs), erasable programmable ROMs (EPROMs), electrically erasable programmable ROMs (EEPROMs), flash memory, magnetic or optical cards, solid-state memory devices, or other types of physical media suitable for storing electronic instructions.

Further, the subject matter of the present disclosure may also be provided as a computer program product including a transitory machine-readable signal (in compressed or uncompressed form). Examples of machine-readable signals, whether modulated using a carrier or unmodulated, include, but are not limited to, signals that a computer system or machine hosting or running a computer program may be configured to access, including signals transferred by one or more networks. For example, a transitory machine-readable signal may comprise transmission of software by the Internet.

Separate instances of these programs can be executed on or distributed across any number of separate computer systems. Thus, although certain steps have been described as being performed by certain devices, software programs, processes, or entities, this need not be the case. A variety of alternative implementations will be understood by those having ordinary skill in the art.

Additionally, those having ordinary skill in the art readily recognize that the techniques described above can be utilized in a variety of devices, environments, and situations. Although the subject matter has been described in language specific to structural features or methodological acts, it is to be understood that the subject matter defined in the appended claims is not necessarily limited to the specific features or acts described. Rather, the specific features and acts are disclosed as exemplary forms of implementing the claims.

What is claimed is:

1. A customer premise equipment (CPE) device, comprising:
an input, coupled to a power supply, to receive an input supply voltage from the power supply;
a filter, coupled to the input, the filter receiving the input supply voltage to produce a filtered input ripple voltage having a predetermined frequency range;
a peak detector, coupled to the filter, to process the filtered input ripple voltage from the filter to generate a peak value signal having an amplitude indicative of a peak value of the filtered input ripple voltage; and
a level detector, coupled to the peak detector, to process the peak value signal to generate a signal indicative of a fault condition of the power supply based on the filtered input ripple voltage being determined to be greater than a predetermined peak input ripple voltage.

2. The CPE of claim 1 further comprises a processor, coupled to the level detector, to provide the signal indicative of the fault condition of the power supply to a broadband service provider.

3. The CPE of claim 1 further comprises a processor, coupled to the level detector, wherein the processor logs the fault condition, and provides the signal indicative of the fault condition to a broadband service provider when the fault condition is logged more than a predetermined number of times over a predetermined period.

4. The CPE of claim 1, wherein the fault condition comprises an indication to a broadband service provider to replace the power supply.

5. The CPE of claim 1 further comprises:
an AC coupling at the input to receive the input supply voltage and to produce the input supply voltage having DC voltage removed from the input supply voltage; and
an amplifier, coupled to the AC coupling, to amplify the input supply voltage having the DC voltage removed from the input supply voltage;
wherein the filter comprises a bandpass filter that passes frequencies within the predetermined frequency range and rejects frequencies outside the predetermined frequency range.

6. The CPE of claim 1, wherein the input supply voltage is a positive 12 volts and wherein the filtered input ripple voltage comprises filtered input ripple voltage of ±120 millivolts.

7. The CPE of claim 1, wherein the signal indicative of the fault condition of the power supply comprises an indication of a capacitor failure in the power supply.

8. A method for providing pre-emptive power supply failure notification, comprising:
receiving, at an input of a customer premise equipment (CPE) device, an input supply voltage from a power supply;
filtering the input supply voltage to produce a filtered input ripple voltage having a predetermined frequency range;
processing the filtered input ripple voltage from the filter to generate a peak value signal having an amplitude indicative of a peak value of the filtered input ripple voltage; and
processing the peak value signal to generate a signal indicative of a fault condition of the power supply based on the filtered input ripple voltage being determined to be greater than a predetermined peak input ripple voltage.

9. The method of claim 8 further comprises providing the signal indicative of the fault condition of the power supply to a broadband service provider.

10. The method of claim 8 further comprising logging the fault condition, and providing the signal indicative of the fault condition to a broadband service provider when the fault condition is logged more than a predetermined number of times over a predetermined period.

11. The method of claim 8, wherein the fault condition comprises an indication to a broadband service provider to replace the power supply.

12. The method of claim 8 further comprises:
AC coupling the input supply voltage to produce the input supply voltage having DC voltage removed from the input supply voltage; and
amplifying the input supply voltage having the DC voltage removed from the input supply voltage prior to filtering the input supply voltage;
wherein the filtering the input supply voltage comprises bandpass filtering the input supply voltage having the DC voltage removed from the input supply voltage to pass frequencies within the predetermined frequency range and to reject frequencies outside the predetermined frequency range.

13. The method of claim 8, wherein the receiving the input supply voltage from the power supply comprises receiving a positive 12-volt input supply voltage, and wherein the determining the filtered input ripple voltage is greater than a predetermined peak input ripple voltage further comprises determining the filtered input ripple voltage is greater than ±120 millivolts.

14. The method of claim 8, wherein the generating the signal indicative of the fault condition of the power supply further comprises generating a signal indicative of a capacitor failure in the power supply.

15. A non-transitory computer-readable media having computer-readable instructions stored thereon, which when executed by a processor causes the processor to perform operations comprising:
receiving, at an input of a customer premise equipment (CPE) device, an input supply voltage from a power supply;
filtering the input supply voltage to produce a filtered input ripple voltage having a predetermined frequency range;
processing the filtered input ripple voltage from the filter to generate a peak value signal having an amplitude indicative of a peak value of the filtered input ripple voltage; and
processing the peak value signal to generate a signal indicative of a fault condition of the power supply based on the filtered input ripple voltage being determined to be greater than a predetermined peak input ripple voltage.

16. The non-transitory computer-readable media of claim 15 further comprises providing the signal indicative of the fault condition of the power supply to a broadband service provider, and wherein the generating the signal indicative of the fault condition of the power supply further comprises generating a signal indicative of a capacitor failure in the power supply.

17. The non-transitory computer-readable media of claim 15 further comprising logging the fault condition, and providing the signal indicative of the fault condition to a broadband service provider when the fault condition is logged more than a predetermined number of times over a predetermined period.

18. The non-transitory computer-readable media of claim 15, wherein the fault condition comprises an indication to a broadband service provider to replace the power supply.

19. The non-transitory computer-readable media of claim 15 further comprises:
AC coupling the input supply voltage to produce the input supply voltage having DC voltage removed from the input supply voltage; and
amplifying the input supply voltage having the DC voltage removed from the input supply voltage prior to filtering the input supply voltage;
wherein the filtering the input supply voltage comprises bandpass filtering the input supply voltage having the DC voltage removed from the input supply voltage to pass frequencies within the predetermined frequency range and to reject frequencies outside the predetermined frequency range.

20. The non-transitory computer-readable media of claim 15, wherein the receiving the input supply voltage from the power supply comprises receiving a positive 12-volt input supply voltage, and wherein the determining the filtered input ripple voltage is greater than a predetermined peak input ripple voltage further comprises determining the filtered input ripple voltage is greater than ±120 millivolts.
